(19) United States
(12) Patent Application Publication
(10) Pub. No.: US 2019/0066760 A1
(43) Pub. Date: Feb. 28, 2019

(54) DRAM AND METHOD FOR OPERATING THE SAME

(71) Applicant: NANYA TECHNOLOGY CORPORATION, New Taipei City (TW)

(72) Inventors: Chung-Hsun LEE, NEW TAIPEI CITY (TW); Hsien-Wen LIU, LUZHU TOWNSHIP (TW)

(21) Appl. No.: 15/684,384

(22) Filed: Aug. 23, 2017

(51) Int. Cl. G11C 11/408; G11C 11/4076; G11C 11/4078; G11C 11/4091

(52) U.S. Cl. CPC G11C 11/4085; G11C 11/4091; G11C 11/4078; G11C 11/4076

(57) ABSTRACT

The present disclosure provides a DRAM. The DRAM includes a memory array and a control device. The memory array has a plurality of word lines configured to control memory cells. The control device is configured to operate at least one word line of the word lines, derive an information on the operating of the at least word line, and cease maintaining data stored in the memory cells controlled by the at least one word line when the information satisfies a condition.

### TECHNICAL FIELD

The present disclosure relates to a dynamic random access memory (DRAM), and more particularly, to a DRAM and method for operating a DRAM.

### DISCUSSION OF THE BACKGROUND

Dynamic random access memory (DRAM) is a type of random access memory that stores each bit of data in a separate capacitor. A simplest DRAM cell comprises a single N-type metal-oxide-semiconductor (NMOS) transistor and a single capacitor. If charges are stored in the capacitor, the cell is said to store a logic HIGH, depending on the convention used. If no charge is present, the cell is said to store a logic LOW. Because the charges in the capacitor dissipate over time, DRAM systems require additional refreshing circuitries to periodically refresh the charges stored in the capacitors. Since a capacitor can store only a very limited amount of charges, in order to quickly distinguish the difference between a logic 1 and a logic 0, two bit lines (BLs) are typically used for each bit, wherein the first in the bit line pair is known as a bit line true (BLT) and the other is the bit line complement (BLC). The single NMOS transistor's gate is controlled by a word line (WL).

This Discussion of the Background section is for background information only. The statements in this Discussion of the Background are not an admission that the subject matter disclosed in this section constitutes a prior art to the present disclosure, and no part of this section may be used as an admission that any part of this application, including this Discussion of the Background section, constitutes prior art to the present disclosure.

### SUMMARY

One aspect of the present disclosure provides a DRAM. The DRAM includes a memory array and a control device. The memory array has a plurality of word lines configured to control memory cells. The control device is configured to operate at least one word line of the word lines, derive an information on the operating of the at least word line, and cease maintaining data stored in the memory cells controlled by the at least one word line when the information satisfies a condition.

In some embodiments, the control device is configured to cease maintaining the data stored in the memory cells controlled by the at least one word line by overwriting the data with a new data when the information satisfies the condition.

In some embodiments, the control device is configured to cease maintaining the data stored in the memory cells controlled by the at least one word line by changing one or more bits of the data when the information satisfies the condition.

In some embodiments, the control device derives a timing information on the operating of the at least one word line, and ceases to maintain the data when the timing information satisfies a timing condition.

In some embodiments, the timing information includes an information on a timing point at which the control device operates the at least one word line, and the timing condition includes a timing length, wherein the control device ceases to maintain the data when a period of time elapsed starting from the timing point satisfies the timing length.

In some embodiments, the timing information includes an information on a time for which the at least one word line is operated in response to the same command in a period, wherein the timing condition includes a threshold time, wherein the control device ceases to maintain the data when the time satisfies the threshold time.

In some embodiments, the control device derives a command-type information on the operating of the at least one word line, and ceases to maintain the data when the command-type information satisfies a type condition.

In some embodiments, the command-type information includes an information on a first type of a command, wherein in response to the first type of command the at least one word line is operated after the at least one word line is operated in response to a second type of a command.

In some embodiments, the at least one word line is a first word line, and another word line of the word lines is a second word line, wherein when the information satisfies the condition, the control device stops maintaining the data by no longer refreshing the first word line and continues refreshing the second word line.

In some embodiments, the at least one word line is a first word line, and another word line of the word lines is a second word line, wherein the control device receives a secure command and an address of the first word line, identifies the first word line as a target word line, derives the information on operating the first word line from the secure command, masks the first word line identified as the target word line, and refreshes the second word line without refreshing the masked first word line when the information satisfies the condition.

Another aspect of the present disclosure provides a method. The method includes operating a word line configured to control memory cells; determining whether an information on the operating of the word line satisfies a condition; and ceases to maintain data stored in the memory cells when the information satisfies the condition.

In some embodiments, the ceasing to maintain the data stored in the memory cells when the information satisfies the condition includes ceasing to maintain the data stored in the memory cells by overwriting the data with a new data.

In some embodiments, the ceasing to maintain the data stored in the memory cells when the information satisfies the condition includes ceasing to maintain the data stored in the memory cells by changing one or more bits of the data when the information satisfies the condition.

In some embodiments, the determining whether the information on the operating of the word line satisfies the condition includes deriving a timing information on the operating of the word line; and determining whether the timing information satisfies a timing condition.

In some embodiments, the deriving the timing information on the operating of the word line includes deriving a timing information on a timing point at which the word line is operated. The determining whether the timing information satisfies the timing condition includes determining whether a period of time elapsed starting from the timing point satisfies a timing length.

In some embodiments, the deriving the timing information on the operating of the word line includes deriving a timing information on a time for which the word line is operated in response to the same command in a period. The determining whether the timing information satisfies the timing condition includes determining whether the time satisfies a threshold time.

In some embodiments, the determining whether the information on the operating of the word line satisfies the condition includes deriving a command-type information on the operating of the word line, and determining whether the command-type information satisfies a type condition.

In some embodiments, the deriving the command-type information on the operating of the word line includes deriving an information, on a first type of a command in response to which a word line is operated after the word line is operated in response to a second type of a command. The determining whether the command-type information satisfies the type condition includes determining whether the first type satisfies a predetermined type.

In some embodiments, the word line is a first word line; the ceasing to maintain the data stored in the memory cells controlled by the word line when the information satisfies the condition includes ceasing to maintain the data by ceasing to refresh the word line when the information satisfies the condition and also includes continuing to refresh the second word line when the information satisfies the condition.

In some embodiments, the word line is a first word line. The method further includes receiving a secure command; receiving an address of the first word line; identifying the first word line as a target word line; deriving the information on the operating of the first word line from the secure command; masking the first word line identified as the target word line; and refreshing the second word line without refreshing the masked first word line when the information satisfies the condition.

In some applications, an owner of the DRAM may wish to protect the data from being leaked. For example, the owner would like to protect the data stored in the memory cells associated with the word line. By means of the approach of the present disclosure, the owner is able to set up some conditions related to operations on the word line by, for example, transmitting the command to the control device via a host. When the conditions are satisfied, the control device ceases to maintain the data associated with the word line 140. Accordingly, the data will eventually be eliminated. As a result, the owner can protect the data from being leaked.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be connected to the figures' reference numbers, which refer to similar elements throughout the description, and:

FIG. 1 is a schematic diagram of a dynamic random access memory (DRAM), in accordance with some embodiments of the present disclosure.

FIG. 2 is a schematic diagram illustrating operating a word line of the DRAM shown in FIG. 1, in accordance with some embodiments of the present disclosure.

FIG. 3 is a schematic diagram illustrating a refresh operation of the DRAM shown in FIG. 1, in accordance with some embodiments of the present disclosure.

FIG. 4 is a schematic diagram illustrating another refresh operation of the DRAM shown in FIG. 1, in accordance with some embodiments of the present disclosure.

FIG. 5 is a flow diagram of a method, in accordance with some embodiments of the present disclosure.

FIG. 6 is a schematic diagram illustrating operating the word line of the DRAM shown in FIG. 1, in accordance with some embodiments of the present disclosure.

FIG. 7 is a flow diagram of operations of the operation of the method shown in FIG. 5, in accordance with some embodiments of the present disclosure.

FIG. 8 is a schematic diagram illustrating operating the word line of the DRAM shown in FIG. 1, in accordance with some embodiments of the present disclosure.

FIG. 9 is a flow diagram of operations of the operation of the method shown in FIG. 5, in accordance with some embodiments of the present disclosure.

FIG. 10 is a schematic diagram illustrating an operation of the word line of the DRAM shown in FIG. 1, in accordance with some embodiments of the present disclosure.

FIG. 11 is a schematic diagram illustrating another operation of the word line of the DRAM shown in FIG. 1, in accordance with some embodiments of the present disclosure.

FIG. 12 is a flow diagram of operations of the operation of the method shown in FIG. 5, in accordance with some embodiments of the present disclosure.

FIG. 13 is a schematic diagram illustrating operating the word line of the DRAM shown in FIG. 1, in accordance with some embodiments of the present disclosure.

FIG. 14 is a flow diagram of operations of the operation of the method shown in FIG. 5, in accordance with some embodiments of the present disclosure.

FIG. 15 is a schematic diagram illustrating an operation of the word line of the DRAM shown in FIG. 1, in accordance with some embodiments of the present disclosure.

FIG. 16 is a schematic diagram illustrating another operation of the word line of the DRAM shown in FIG. 1, in accordance with some embodiments of the present disclosure.

FIG. 17 is a flow diagram of operations of the operation of the method shown in FIG. 5, in accordance with some embodiments of the present disclosure.

FIG. 18 is a flow diagram of another method, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

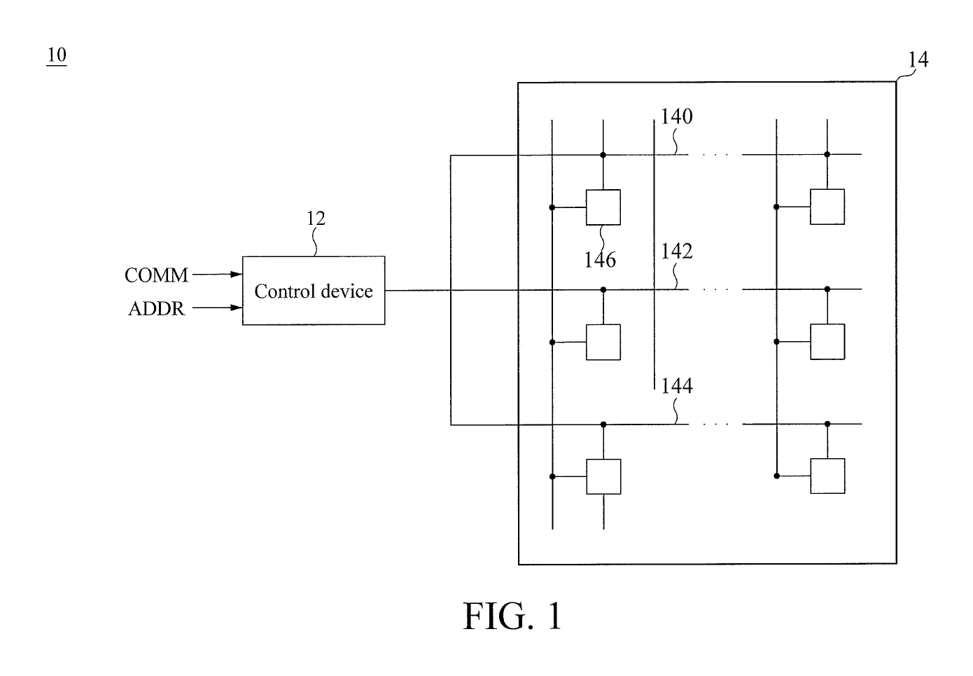

FIG. 1 is a schematic diagram of a dynamic random access memory (DRAM) 10, in accordance with some embodiments of the present disclosure. Referring to FIG. 1, the DRAM 10 includes a control device 12, and a memory array 14 including a plurality of word lines 140, 142 and 144.

The control device 12 functions to control access of the word lines 140, 142 and 144, so as to, for example, read or write data stored in memory cells 146 associated with the word lines 140, 142 and 144. In further detail, the control device 12 receives a command COMM and an address ADDR, and performs an operation indicated by the command COMM on a word line, associated with the address ADDR, among the word lines 140, 142 and 144. For convenience of discussion, in the following context, the address ADDR is associated with the word line 140.

The word line 140 controls memory cells 146 being connected thereto. The word lines 142 and 144 have the same function as the word line 140. For clarity of illustration, in the following discussion, each of the word lines 140, 142 and 144 is depicted as a block, and the memory cells 146 are omitted.

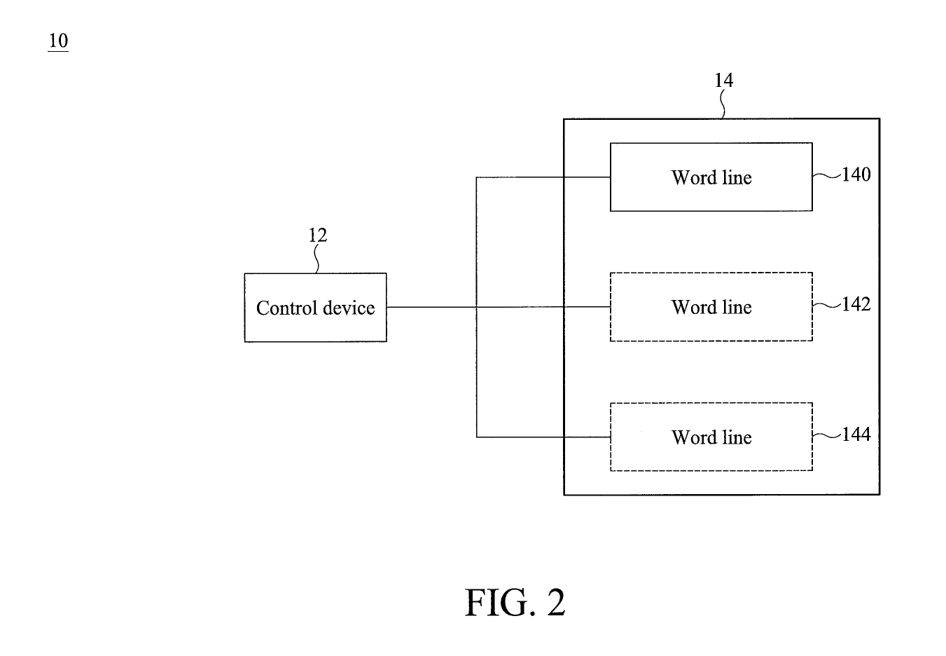

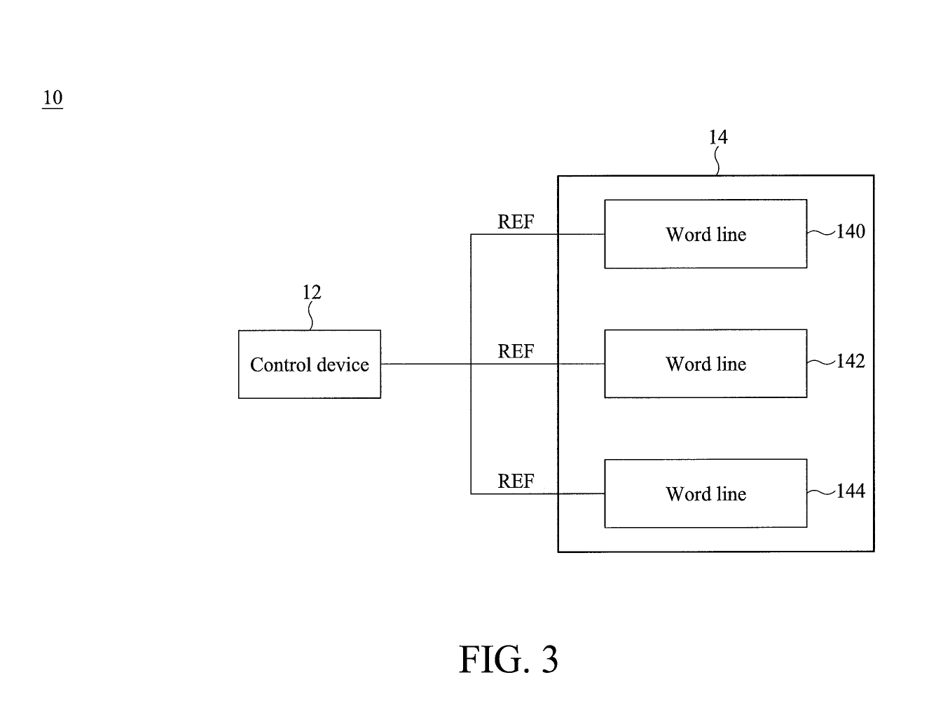

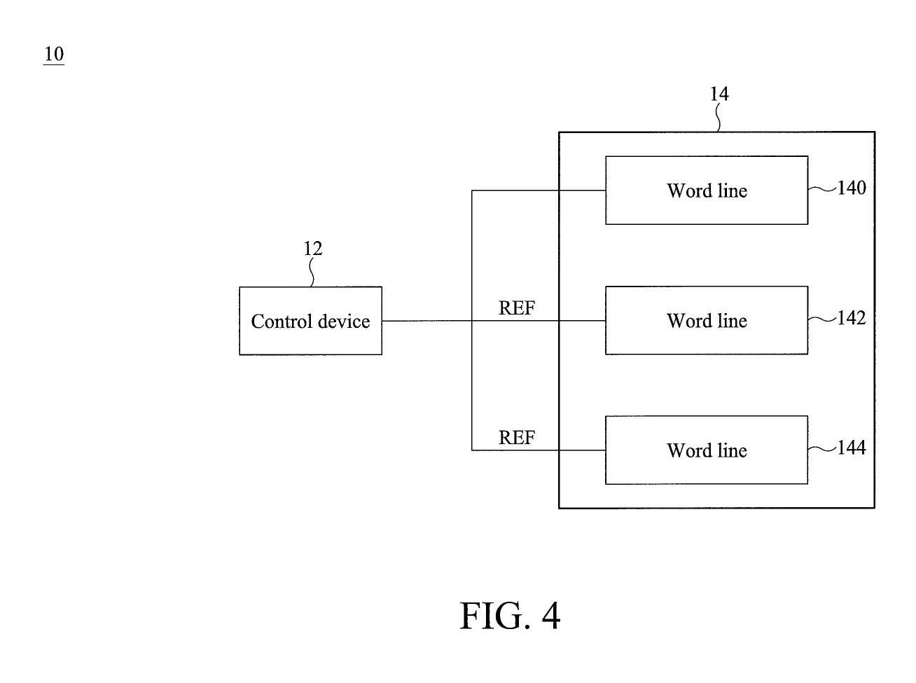

FIG. 2 is a schematic diagram illustrating operating the word line 140 of the DRAM 10 shown in FIG. 1, in accordance with some embodiments of the present disclosure. Referring to FIG. 2, the control device 12 operates the word line 140 based on the address ADDR. Additionally, the control device 12 derives a condition from the command COMM. However, the present disclosure is not limited thereto. The control device 12 may derive the condition from another source. Next, the control device 12 determines whether an information on the operating of the word line 140 satisfies the condition derived from the command COMM. If negative, the control device 12 continues to maintain the data stored in the memory cells 146 associated with the word line 140 as shown in FIG. 3. If affirmative, the control device 12 ceases to maintain the data stored in the memory cells 146 controlled by the word line 140 as shown in FIG. 4.

In an embodiment, the control device 12 ceases maintaining the data stored in the memory cells 146 controlled by the word line 140 by overwriting the data with a new data when the information satisfies the condition. In another embodiment, The control device 12 ceases maintaining the data stored in the memory cells 146 controlled by the word line 140 by changing one or more bits of the data when the information satisfies the condition.

In some applications, an owner of the DRAM 10 may wish to protect the data from being leaked. For example, the owner would like to protect the data stored in the memory cells 146 associated with the word line 140 from being leaked. By means of the approach of the present disclosure, the owner is able to set up some conditions related to operations on the word line 140 by, for example, transmitting the command COMM to the control device 12 via a host. When the conditions are satisfied, the control device 12 ceases to maintain the data associated with the word line 140. Accordingly, the data will eventually be eliminated. Even though an un-authorized user may read something stored in the memory cells 146 associated with the word line 140, that thing is not the data which the owner would like to protect since the data has been eliminated. As a result, the owner can protect the data from being leaked.

FIG. 3 is a schematic diagram illustrating a refresh operation of the DRAM 10 shown in FIG. 1, in accordance with some embodiments of the present disclosure. Referring to FIG. 3, the control device 12 determines that the information does not satisfy the condition, and therefore the control device 12 continues to maintain the data by refreshing the word line 140 in addition to refreshing the word lines 142 and 144.

FIG. 4 is a schematic diagram illustrating another refresh operation of the DRAM 10 shown in FIG. 1, in accordance with some embodiments of the present disclosure. Referring to FIG. 4, the control device 12 determines that the information satisfies the condition, and therefore the control device 12 ceases maintaining the data by not refreshing the word line 140. Moreover, the control device 12 continues refreshing the word lines 142 and 144 without refreshing the word line 140. Accordingly, the data associated with the word line 140 will eventually be eliminated. As a result, the owner can protect the data from being leaked.

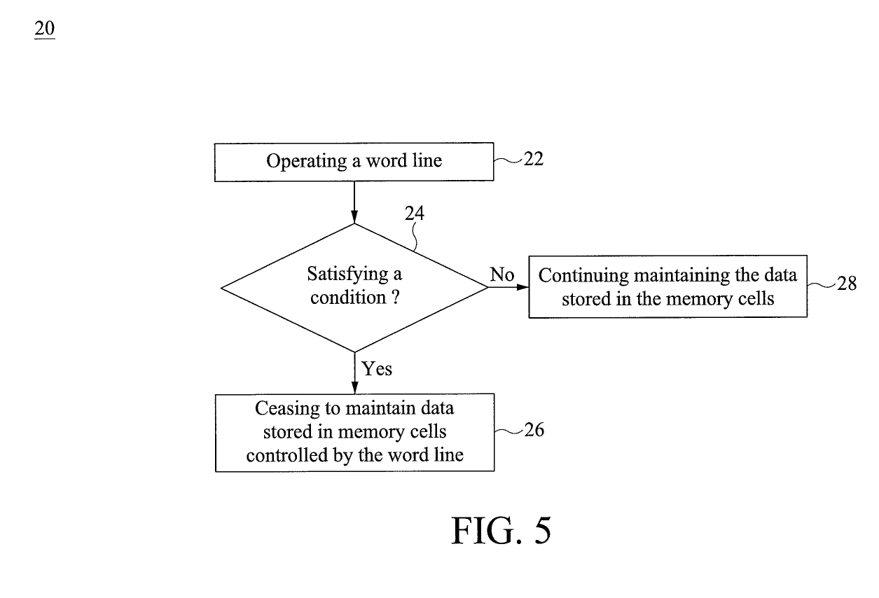

FIG. 5 is a flow diagram of a method 20, in accordance with some embodiments of the present disclosure. Referring to FIG. 5, the method 20 includes operations 22, 24, 26 and 28. The method 20 begins with operation 22, in which a word line is operated. The method 20 continues with operation 24, in which it is determined whether an information on the operating of the word line satisfies a condition. If affirmative, the method 20 proceeds to operation 26, in which data stored in memory cells controlled by the word line ceases to be maintained. Accordingly, the data will eventually be eliminated. As a result, an owner of a DRAM can protect the data from being leaked. If negative, the method 20 continues with operation 28, in which the data stored in the memory cells continues to be maintained.

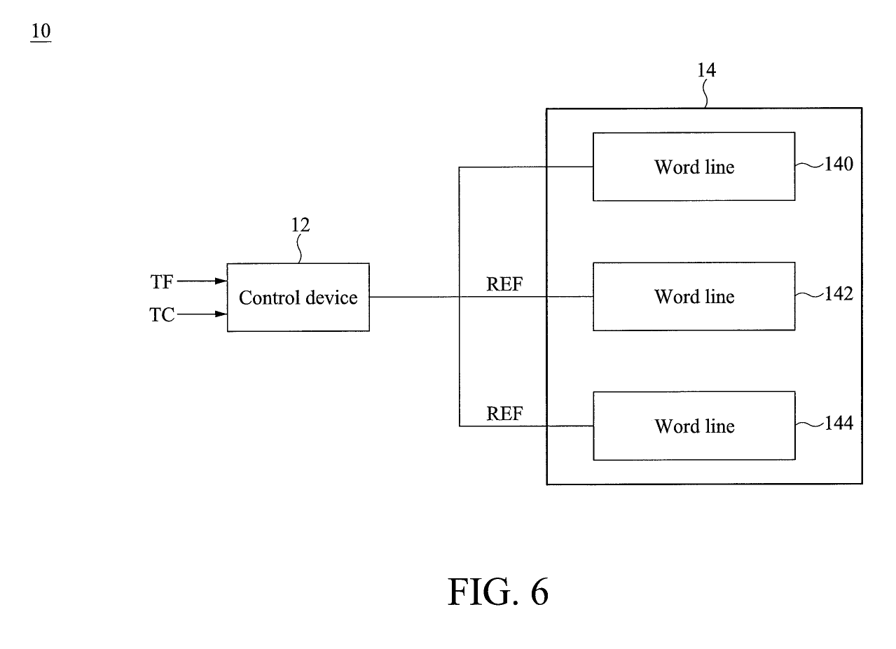

FIG. 6 is a schematic diagram illustrating operating the word line 140 of the DRAM 10 shown in FIG. 1, in accordance with some embodiments of the present disclosure. Some detailed descriptions are similar to those presented above in the descriptions of FIGS. 1 and 2. Therefore, the detailed descriptions are omitted herein. The information and the condition mentioned in the embodiment of FIGS. 1 and 2 respectively include a timing information TI and a timing condition TC.

Referring to FIG. 6, the control device 12 controls the word line 140, and derives the timing information TI on the operating of the word line 140. Additionally, the control device 12 derives the timing condition TC from the command COMM. However, the present disclosure is not limited thereto. The control device 12 may derive the timing condition TC from another source. When the control device 12 determines that the timing information TI satisfies the timing condition TC, as shown in FIG. 6, the control device 12 refreshes the word lines 142 and 144 without refreshing the word line 140, and the control device 12 ceases to refresh the word line 140. Accordingly, the data stored in the memory cells 146 controlled by the word line 140 will eventually be eliminated. As a result, the owner can protect the data from being leaked.

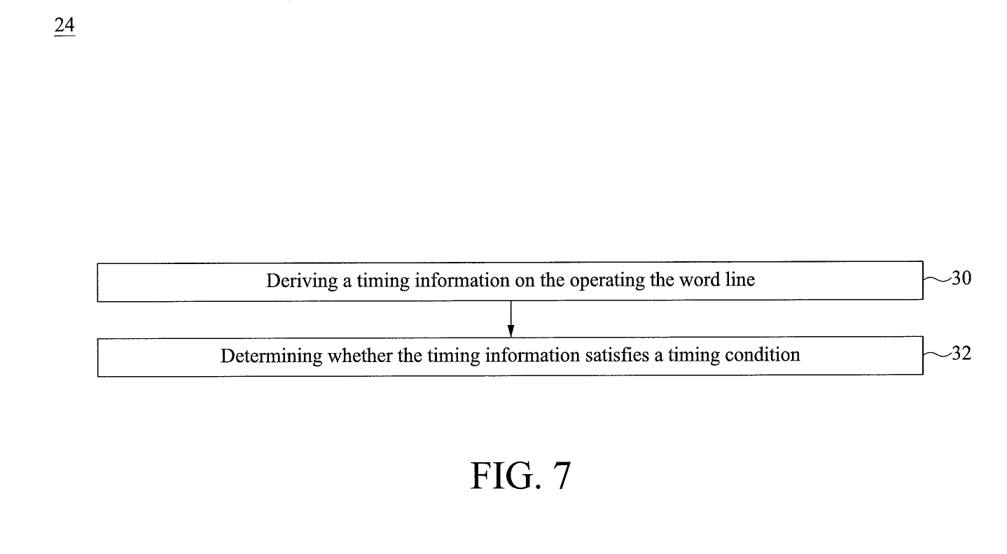

FIG. 7 is a flow diagram of operations of operation 24 of the method 20 shown in FIG. 5, in accordance with some embodiments of the present disclosure. Referring to FIG. 7, operation 24 includes operations 30 and 32. Operation 24 begins with operation 30, in which a timing information on the operating of the word line is derived. Operation 24 continues with operation 32, in which it is determined whether the timing information satisfies a timing condition. If affirmative, as mentioned in the description of FIG. 5, the word line is ceased to be refreshed. Accordingly, the data stored in the memory cells controlled by the word line will eventually be eliminated. As a result, the owner can protect the data from being leaked.

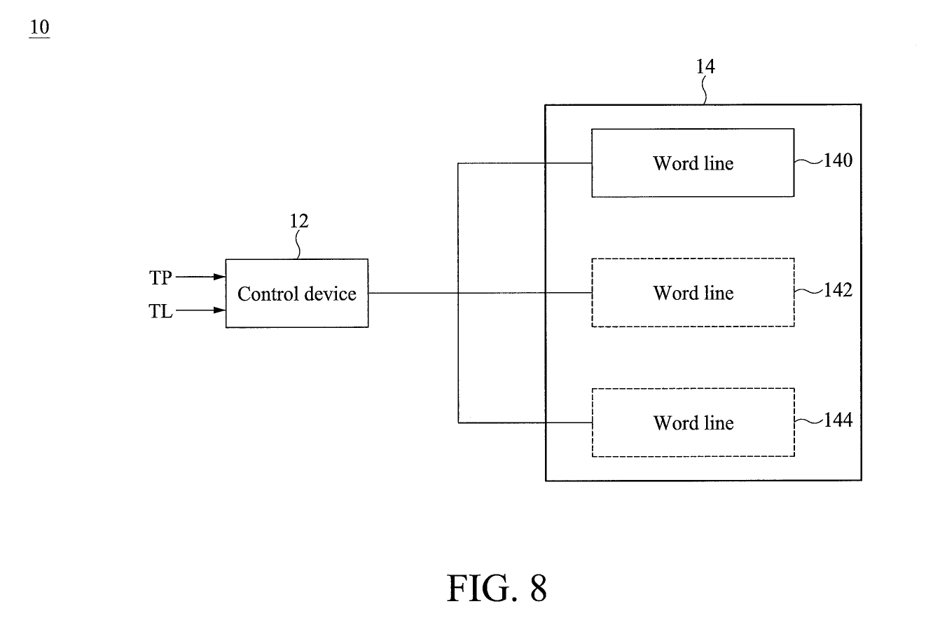

FIG. 8 is a schematic diagram illustrating operating the word line 140 of the DRAM 10 shown in FIG. 1, in accordance with some embodiments of the present disclosure. Referring to FIG. 8, the timing information TI mentioned in the description of FIG. 6 includes an information on a timing point TP, at which the word line 140 is operated. The timing condition TC mentioned in the description of FIG. 6 includes a timing length TL.

The control device 12 derives the timing length TL from the command COMM. However, the present disclosure is not limited thereto. The control device 12 may derive the timing length TL from another source. When the control device 12 determines that a period of time elapsed starting from the timing point TP satisfies the timing length TL, as shown in FIG. 6, the control device 12 refreshes the word lines 142 and 144, and the control device 12 ceases to refresh the word line 140. Accordingly, the data stored in the memory cells 146 controlled by the word line 140 will eventually be eliminated. As a result, the owner can protect the data from being leaked.

In some embodiments, the control device 12 performs the determination directly based on the timing length TL. For example, the timing length TL is about 5 minutes. The control device 12 determines whether a period of time elapsed starting from the timing point TP, at which the control device 12 operates the word line 140, reaches 5 minutes. If affirmative, the control device 12 ceases to refresh the word line 140.

In some embodiments, the control device 12 performs the determination indirectly based on the timing length TL. In further detail, the control device 12 converts the timing length TL into the amount of refresh cycles of the word line 140. Accordingly, the control device 12 determines whether a period of time elapsed starting from the timing point TP, at which the control device 12 operates the word line 140, reaches a target refresh cycles by, for example, using a counter (not shown). If affirmative, the control device 12 ceases refreshing the word line 140.

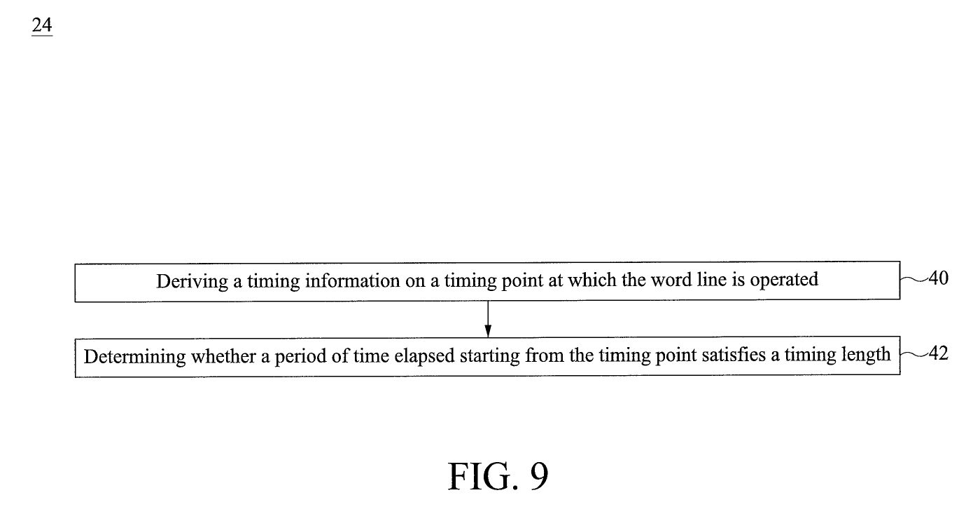

FIG. 9 is a flow diagram of operations of operation 24 of the method 20 shown in FIG. 5, in accordance with some embodiments of the present disclosure. Referring to FIG. 9, operation 24 includes operations 40 and 42. Operation 24 begins with operation 40, in which a timing information on a timing point at which the word line is operated is derived. Operation 24 continues with operation 42, in which it is determined whether a period of time elapsed starting from the timing point satisfies a timing length. If affirmative, as mentioned in the description of FIG. 5, the word line is ceased to be refreshed. Accordingly, the data stored in the memory cells controlled by the word line will eventually be eliminated. As a result, the owner can protect the data from being leaked.

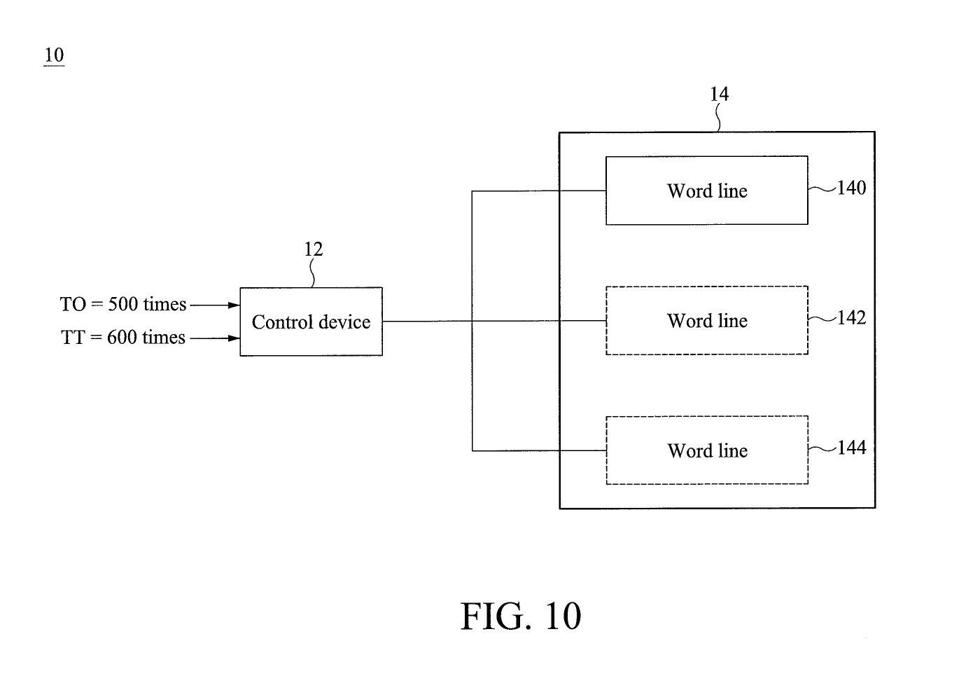

FIG. 10 is a schematic diagram illustrating an operation of the word line 140 of the DRAM 10 shown in FIG. 1, in accordance with some embodiments of the present disclosure. Referring to FIG. 10, the timing information TI mentioned in the description of FIG. 6 includes a timing information on a time TO, for which the word line 140 is operated in response to the same command in a period. That is, the time TO includes the number of operations on the word line 140 in response to the same command in a period. Moreover, the timing condition TC mentioned in the description of FIG. 6 includes a threshold time TT in a period.

The control device 12 derives the threshold time TT from the command COMM. However, the present disclosure is not limited thereto. The control device 12 may derive the threshold time TT from another source. When the control device 12 determines that the time TO does not satisfy the threshold time TT, the control device 12 continues refreshing the word line 140, thereby maintaining the data.

For example, the threshold time TT is 600 times in a period. In the embodiment of FIG. 10, the control device 12 operates the word line 140 in a period in response to the same, for example, read-type command, for 500 times of the time TO. Since 500 times is less than 600 times of the threshold time TT, the control device 12 continues refreshing the word line 140.

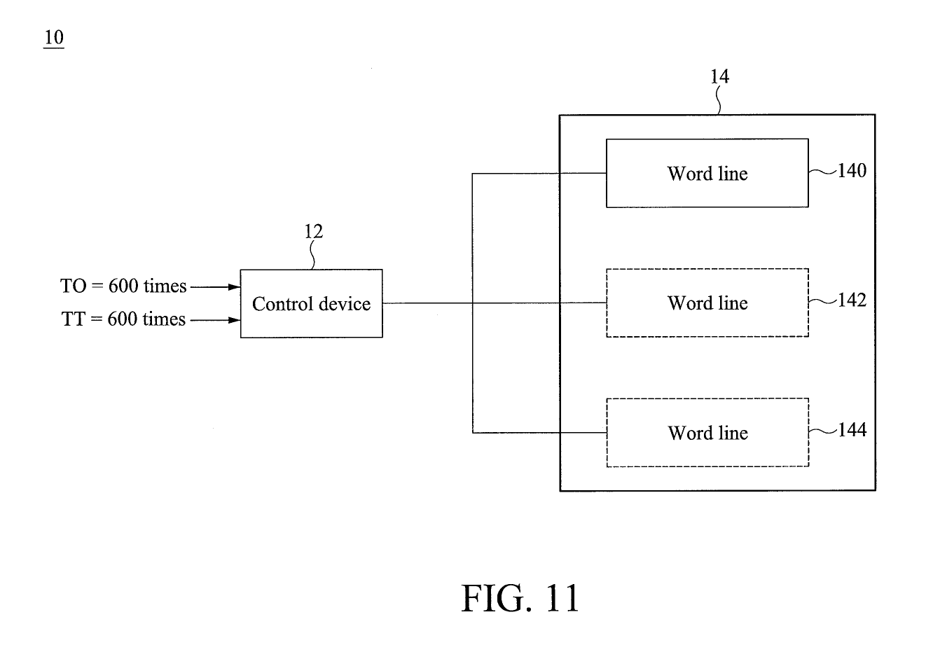

FIG. 11 is a schematic diagram illustrating another operation of the word line 140 of the DRAM 10 shown in FIG. 1, in accordance with some embodiments of the present disclosure. Referring to FIG. 11, the control device 12 operates the word line 140 in a period in response to the same, for example, read-type command, for 500 times of the time TO. Since 500 times of the time TO reaches 600 times of the threshold time TT, the control device 12 ceases refreshing the word line 140. Accordingly, the data stored in the memory cells 146 controlled by the word line 140 will eventually be eliminated. As a result, the owner can protect the data from being leaked.

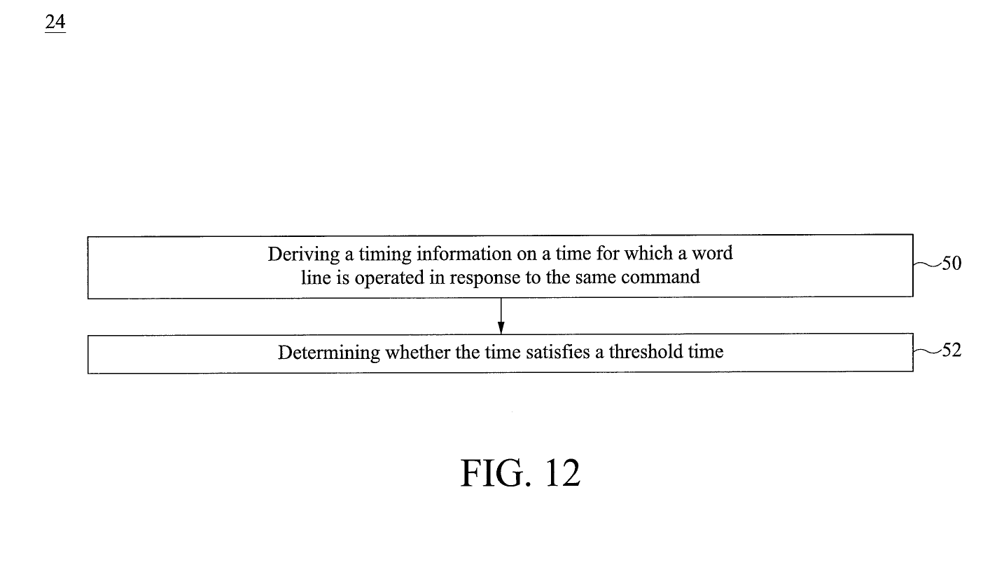

FIG. 12 is a flow diagram of operations of operation 24 of the method 20 shown in FIG. 5, in accordance with some embodiments of the present disclosure. Referring to FIG. 12, operation 24 includes operations 50 and 52. Operation 24 begins with operation 50, in which a timing information on a time for which a word line is operated in response to the same command is derived. Operation 24 continues with operation 52, in which it is determined whether the time satisfies a threshold time. If affirmative, as mentioned in the description of FIG. 5, the word line ceases to be refreshed. Accordingly, the data stored in the memory cells controlled by the word line will eventually be eliminated. As a result, the owner can protect the data from being leaked.

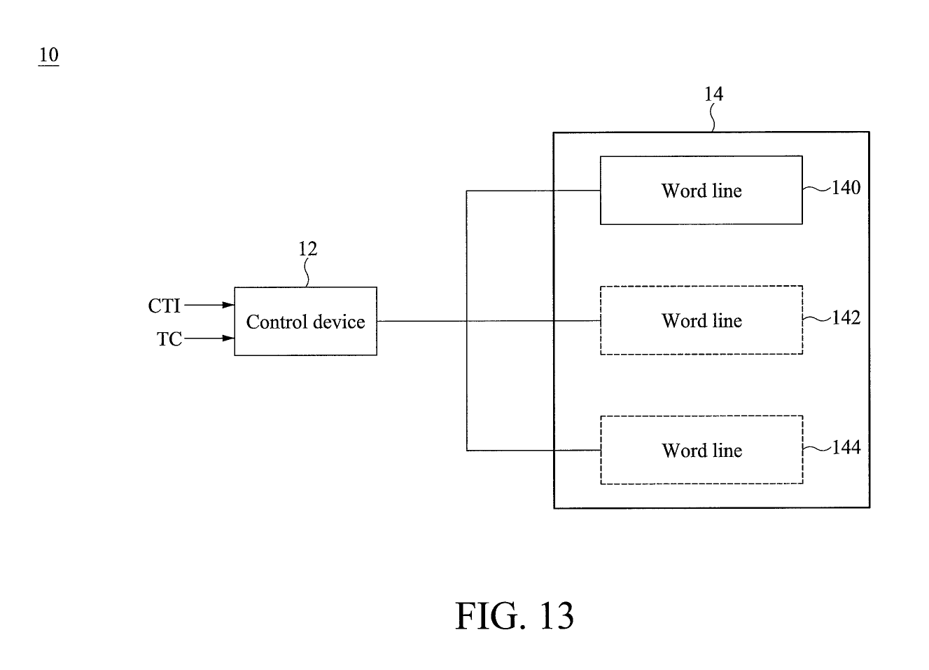

FIG. 13 is a schematic diagram illustrating operating the word line 140 of the DRAM 10 shown in FIG. 1, in accordance with some embodiments of the present disclosure. Referring to FIG. 13, the information mentioned in the descriptions of FIGS. 2, 3 and 4 includes a command-type information CTI. Moreover, the condition mentioned in the descriptions of FIGS. 2, 3 and 4 includes a type condition TC.

The control device 12 derives the type condition TC from the command COMM. However, the present disclosure is not limited thereto. The control device 12 may derive the type condition TC from another source. When the control device 12 determines that the command-type information CTI satisfies the type condition TC, as shown in FIG. 6, the control device 12 refreshes the word lines 142 and 144 without refreshing the word line 140, and no longer refreshes the word line 140. Accordingly, the data stored in the memory cells 146 controlled by the word line 140 will eventually be eliminated. As a result, the owner can protect the data from being leaked.

For example, the owner of the DRAM 10 would like to abandon the data after the owner has read the data. In that case, the owner is able to set up a read-type command as the type condition TC. In operation, the control device 12 performs a read operation on the word line 140 in response to a read-type command of the command COMM. Moreover, the control device 12 derives the read-type command of the type condition TC from the command COMM. Additionally, the control device 12 derives the command-type information CTI on the performing the read operation. Next, the control device 12 determines that the command-type information CTI on the read-type command satisfies the type condition TC of the read-type command. Accordingly, the control device 12 ceases refreshing the word line 140. As a result, the owner is able to abandon the data after the owner reads the data.

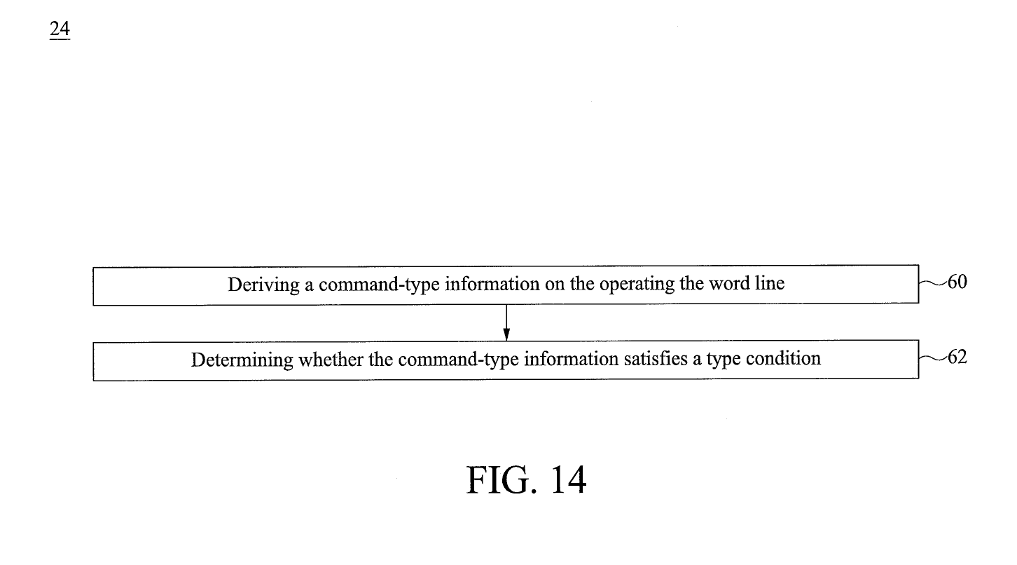

FIG. 14 is a flow diagram of operations of operation 24 of the method 20 shown in FIG. 5, in accordance with some embodiments of the present disclosure. Referring to FIG. 14, operation 24 includes operations 60 and 62. Operation 24 begins with operation 60, in which a command-type information on the operating of the word line is derived. Operation 24 continues with operation 62, in which it is determined whether the command-type information satisfies a type condition. If affirmative, as mentioned in the description of FIG. 5 the word line is no longer refreshed. Accordingly, the data stored in the memory cells controlled by the word line will eventually be eliminated. As a result, the owner can protect the data from being leaked.

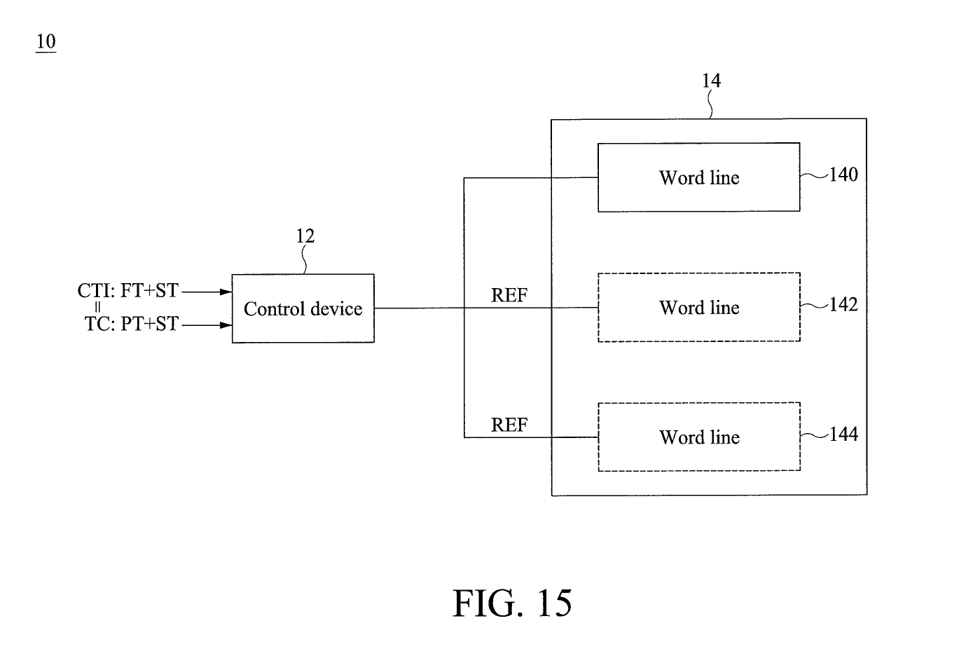

The command-type information CTI and the type condition TC may include an alternative implementation, which will be described and illustrated with reference to FIGS. 15 to 17.

FIG. 15 is a schematic diagram illustrating an operation of the word line 140 of the DRAM 10 shown in FIG. 1, in accordance with some embodiments of the present disclosure. Referring to FIG. 15, the information and the condition mentioned in the descriptions of FIGS. 2, 3 and 4 include a command-type information CTI and a type condition TC, respectively.

The command-type information CTI indicates a first type FT of a command in response to which the word line 140 is operated after the word line 140 is operated in response to a second type ST of a command.

The type condition TC indicates a predetermined type PT of a command, in response to which the word line 140 is operated after the word line 140 is operated in response to the second type ST of a command.

As shown in FIG. 15, the control device 12 operates the word line 140 in response to a first type FT of a command after the control device 12 operates the word line 140 in response to a second type ST of a command. Accordingly, the control device 12 derives the command-type information CTI, on the first type FT of a command, in response to which the control device 12 operates the word line 140 after the control device 12 operates the word line 140 in response to the second type ST of a command. The control device 12 determines that the first type FT of a command satisfies the predetermined type PT. As such, the control device 12 refreshes the word lines 142 and 144 without refreshing the word line 140, and no longer refreshes the word line 140. Accordingly, the data stored in the memory cells 146 controlled by the word line 140 will eventually be eliminated. As a result, the owner can protect the data from being leaked.

In some applications, the owner of the DRAM 10 would like to abandon the data when the control device 12, for example, reads the data from the memory cells 146 after the control device 12, for example, writes the data into the memory cells 146. In that case, the owner sets up a condition that the predetermined type PT is a read type, and the second type ST is a write type.

In operation, the control device 12 operates the word line 140 in response to the read type of a command after operating the word line 140 in response to the write type of a command. Accordingly, the control device 12 determines that the read type serving as the first type FT satisfies the read type serving as the predetermined type PT. As such, the control device 12 refreshes the word lines 142 and 144 and does not refresh the word line 140, and no longer refreshes the word line 140. Therefore, the owner of the DRAM 10 is able to abandon the data when the control device 12 reads the data from the memory cells 146 after the control device 12 writes the data into the memory cells 146.

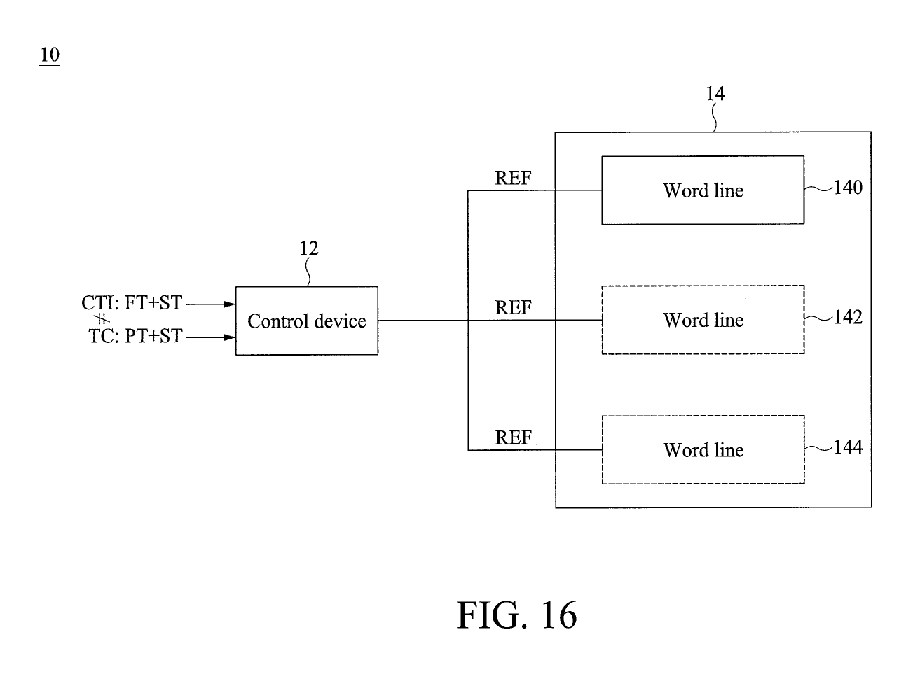

FIG. 16 is a schematic diagram illustrating another operation of the word line 140 of the DRAM 10 shown in FIG. 1, in accordance with some embodiments of the present disclosure. Referring to FIG. 16, the control device 12 determines that the first type FT of a command does not satisfy the predetermined type PT. As such, the control device 12 continues refreshing the word line 140, thereby maintaining the data.

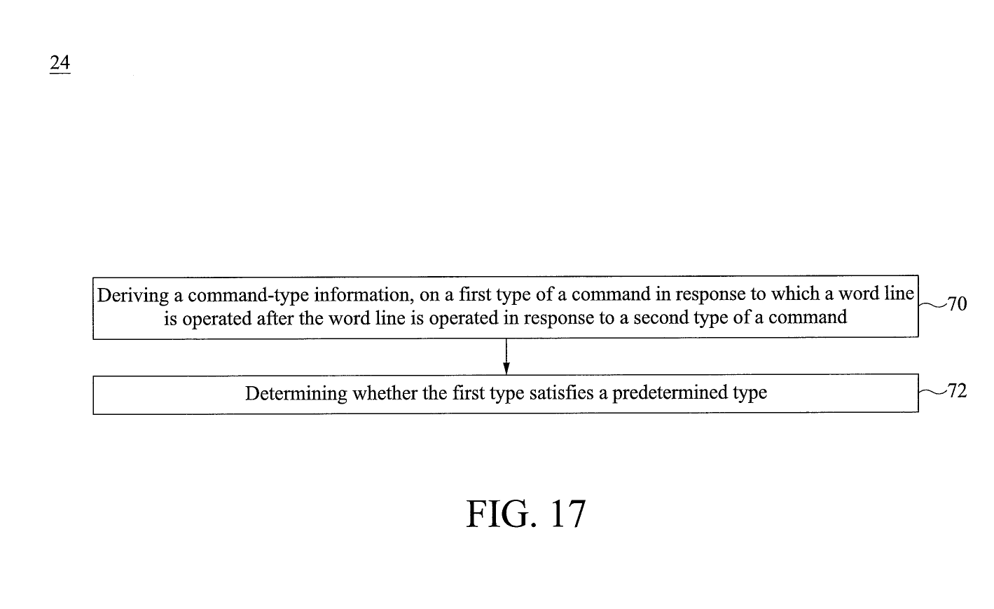

FIG. 17 is a flow diagram of operations of operation 24 of the method 20 shown in FIG. 5, in accordance with some embodiments of the present disclosure. Referring to FIG. 17, operation 24 includes operations 70 and 72.

Operation 24 begins with operation 70, in which a command-type information on a first type of a command, wherein a word line is operated in response to the first type of a command after the word line is operated in response to a second type of a command, is derived. Operation 24 continues with operation 72, in which it is determined whether the first type satisfies a predetermined type. If affirmative, as mentioned in the description of FIG. 5, the word line is no longer refreshed. Accordingly, the data stored in the memory cells controlled by the word line will eventually be eliminated. As a result, the owner can protect the data from being leaked.

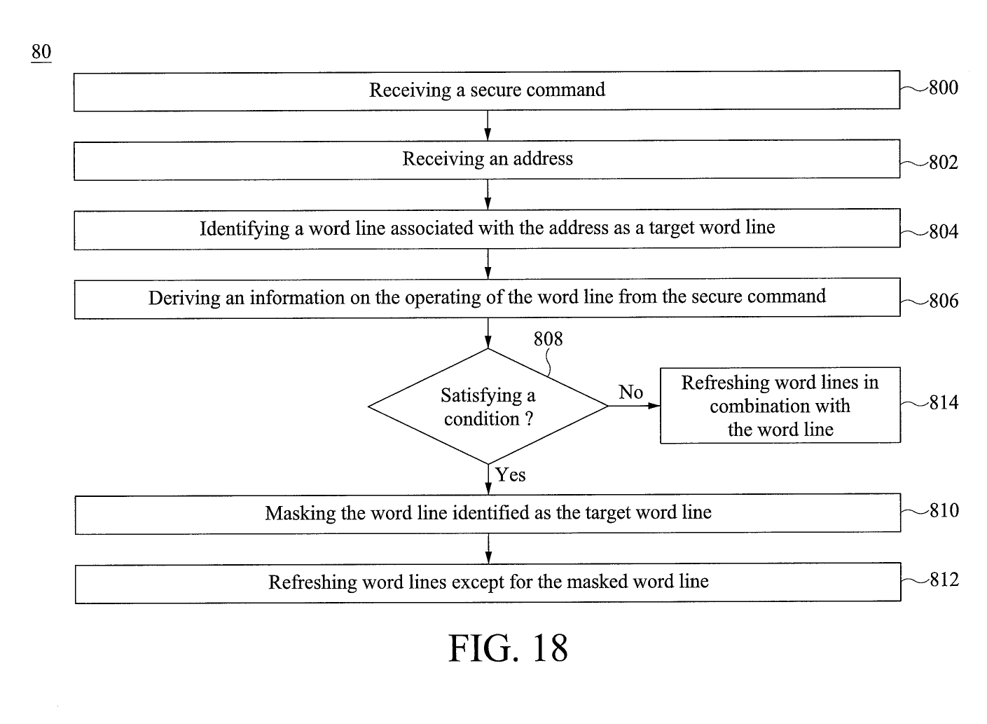

FIG. 18 is a flow diagram of another method 80, in accordance with some embodiments of the present disclosure. The embodiment of FIG. 18 will be discussed accompanied with the DRAM 10 shown in FIG. 1.

Referring to FIG. 18, the method 80 includes operations 800, 802, 804, 806, 808, 810, 812 and 814. The method 80 begins with operation 800, in which the control device 12 receives a secure command analogous to the command COMM. The method 80 proceeds with operation 802, in which the control device 12 receives an address ADDR.

The method 80 continues with operation 804, in which the control device 12 identifies the word line 140 associated with the address ADDR among the word lines 140, 142 and 144 as a target word line. The method 80 proceeds to operation 806, in which an information on the operating of the word line 140 is derived from the secure command COMM.

The method 80 continues with operation 808, in which the control device 12 determines whether the information satisfies the condition. If negative, the method 80 proceeds to operation 814, in which the control device 12 refreshes the word line 140 in combination with the word lines 142 and 144. If affirmative, the method 80 proceeds to operation 810, in which the control device 12 masks the word line 140 identified as the target word line. The method 80 proceeds to operation 812, in which the control device 12 refreshes the word lines 142 and 144 and does not refresh the masked word line 140. Accordingly, the data stored in the memory cells 146 controlled by the word line 140 will eventually be eliminated. As a result, the owner can protect the data from being leaked.

In some applications, an owner of the DRAM 10 would like to protect the data from being leaked. For example, the owner would like to protect the data stored in the memory cells 146 associated with the word line 140. By means of the approach of the present disclosure, the owner is able to set up some conditions related to operations on the word line 140 by, for example, transmitting the command COMM to the control device 12 via a host. When the conditions are satisfied, the control device 12 ceases to maintain the data associated with the word line 140. Accordingly, the data will eventually be eliminated. As a result, the owner can protect the data from being leaked.

One aspect of the present disclosure provides a DRAM. The DRAM includes a word line and a control device. The control device is configured to operate the word line, derive an information on the operating of the word line, and cease to maintain data stored in memory cells controlled by the word line when the information satisfies a condition.

Another aspect of the present disclosure provides a method. The method includes operating a word line; determining whether an information on the operating of the word line satisfies a condition; and ceasing to maintain data stored in memory cells controlled by the word line when the information satisfies the condition.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A dynamic random access memory (DRAM), comprising:
a memory array having a plurality of word lines configured to control memory cells; and
a control device configured to operate at least one word line of the word lines, derive an information on the operating of the at least one word line, and cease maintaining data stored in the memory cells controlled by the at least one word line when the information satisfies a condition.

2. The DRAM of claim 1, wherein the control device is configured to cease maintaining the data stored in the memory cells controlled by the at least one word line by overwriting the data with a new data when the information satisfies the condition.

3. The DRAM of claim 1, wherein the control device is configured to cease maintaining the data stored in the memory cells controlled by the at least one word line by changing one or more bits of the data when the information satisfies the condition.

4. The DRAM of claim 1, wherein the control device derives a timing information on the operating of the at least one word line, and ceases to maintain the data when the timing information satisfies a timing condition.

5. The DRAM of claim 4, wherein the timing information includes an information on a timing point at which the control device operates the at least one word line, and the timing condition includes a timing length, and wherein the control device ceases maintaining the data when a period of time elapsed starting from the timing point satisfies the timing length.

6. The DRAM of claim 4, wherein the timing information includes an information on a time for which the at least one word line is operated in response to the same command in a period, wherein the timing condition includes a threshold time, wherein the control device ceases to maintain the data when the time satisfies the threshold time.

7. The DRAM of claim 1, wherein the control device derives a command-type information on the operating of the at least one word line, and ceases to maintain the data when the command-type information satisfies a type condition.

8. The DRAM of claim 7, wherein the command-type information includes an information, on a first type of a command in response to which the at least one word line is operated after the at least one word line is operated in response to a second type of a command.

9. The DRAM of claim 1, wherein the at least one word line is a first word line, and another word line of the word lines is a second word line, wherein the control device ceases to maintain the data by ceasing to refresh the first word line and continuing refreshing the second word line when the information satisfies the condition.

10. The DRAM of claim 1, wherein the at least one word line is a first word line, and another word line of the word lines is a second word line,
wherein the control device receives a secure command and an address of the first word line, identifies the first word line as a target word line, derives the information on operating the first word line from the secure command, masks the first word line identified as the target word line, and refreshes the second word line without refreshing the masked first word line when the information satisfies the condition.

11. A method, comprising:
operating a word line configured to control memory cells;
determining whether an information on the operating of the word line satisfies a condition; and
ceasing to maintain data stored in the memory cells when the information satisfies the condition.

12. The method of claim 11, wherein the ceasing to maintain the data stored in the memory cells when the information satisfies the condition includes:
ceasing to maintain the data stored in the memory cells by overwriting the data with a new data.

13. The method of claim 11, wherein the ceasing to maintain the data stored in the memory cells when the information satisfies the condition includes:
ceasing to maintain the data stored in the memory cells by changing one or more bits of the data when the information satisfies the condition.

14. The method of claim 11, wherein the determining whether the information on the operating of the word line satisfies the condition includes:
deriving a timing information on the operating of the word line; and
determining whether the timing information satisfies a timing condition.

15. The method of claim 14, wherein the deriving the timing information on the operating of the word line includes:
deriving a timing information on a timing point at which the word line is operated, and
wherein the determining whether the timing information satisfies the timing condition includes:
determining whether a period of time elapsed starting from the timing point satisfies a timing length.

16. The method of claim 14, wherein the deriving the timing information on the operating of the word line includes:
deriving a timing information on a time for which the word line is operated in response to a same command in a period, and
wherein the determining whether the timing information satisfies the timing condition includes:
determining whether the time satisfies a threshold time.

17. The method of claim 11, wherein the determining whether the information on the operating of the word line satisfies the condition includes:
deriving a command-type information on the operating of the word line, and
determining whether the command-type information satisfies a type condition.

18. The method of claim 17, wherein the deriving the command-type information on the operating of the word line includes:
deriving an information, on a first type of a command in response to which a word line is operated after the word line is operated in response to a second type of a command,
wherein the determining whether the command-type information satisfies the type condition includes:
determining whether the first type satisfies a predetermined type.

19. The method of claim 11, wherein the word line is a first word line, and the ceasing to maintain the data stored in the memory cells controlled by the word line when the information satisfies the condition includes:
ceasing to maintain the data by ceasing to refresh the word line when the information satisfies the condition; and
continuing refreshing the second word line when the information satisfies the condition.

20. The method of claim 11, wherein the word line is a first word line, the method further comprising:
receiving a secure command;
receiving an address of the first word line;
identifying the first word line as a target word line;
deriving the information on the operating of the first word line from the secure command;
masking the first word line identified as the target word line; and
refreshing the second word line without refreshing the masked first word line when the information satisfies the condition.
